(19) United States
(12) Patent Application Publication
(10) Pub. No.: US 2025/0267823 A1
(43) Pub. Date: Aug. 21, 2025

(54) TRANSISTOR CARRIER AND COOLING MECHANISM

(71) Applicant: Garrett Transportation I Inc., Torrance, CA (US)

(72) Inventors: Anil Jaswal, Epinal (FR); Christelle Saber, Les Forges (FR); Radhouane Khlissa, Epinal (FR); Benjamin Barthelemy, Gérardmer (FR); Benjamin Chaudy, Thaon-Ies-Vosges (FR); Charles Weiler, Girmont (FR)

(73) Assignee: Garrett Transportation I Inc., Torrance, NC (US)

(21) Appl. No.: 18/583,258

(22) Filed: Feb. 21, 2024

(51) Int. Cl. H05K 7/20; H01L 23/46; H02M 7/00

(52) U.S. Cl. CPC H05K 7/2089; H01L 23/46; H02M 7/003

(57) ABSTRACT

A low loss power inverter including a printed circuit board having an upper surface, a lower surface and an internal layer disposed between the lower surface and the upper surface, a first transistor, disposed on the upper surface, having a first terminal, a second transistor, disposed on the upper surface, having a second terminal, and a decoupling capacitor having a first capacitor terminal conductively coupled to the first terminal via a first trace laminated to the upper surface and a second capacitor terminal conductively coupled to the second terminal via a second trace laminated to the lower surface.

### TECHNICAL FIELD

The present disclosure generally relates to an electric motor switching inverter and, more particularly, relates to a system for providing thermal, noise, vibration and harshness control for inverter circuitry using resilient members to apply a positive force on a switching transistor towards a cooling surface.

### BACKGROUND

The ever increasing use of electric motors in automotive applications continuously introduces new demands for high power, high efficiency and high power density electrical motor drives. For example, some automotive compressors, such as turbochargers, superchargers, or other fluid compression devices can include an electric motor that is operably coupled to the same shaft that supports a compressor wheel, turbine wheel, etc. The electric motor may drivingly rotate the shaft, for example, to assist a turbine stage of the device. These electric motors are typically driven using a three-phase inverter for converting direct current (DC) power to alternating current (AC) power. In a three-phase inverter, high-power MOSFETs can be used to switch various current carrying circuits on and off to create the AC waveforms.

In a turbocharger application, the inherent resistance and switching actions of the MOSFETs generate heat, which worsens at elevated temperatures. Secondly, high ambient temperatures resulting from the close proximity to the turbocharger and associated exhaust pipes further increases the operating temperatures of the MOSFETs adding additional thermal stress and shrinking the safe operating margin of the inverter. Proper cooling of the inverter becomes vital to combat this dual threat and to prevent the MOSFETs from exceeding their temperature limits, ensuring their reliability and lifespan. Additionally, it maintains their electrical characteristics, safeguarding the inverter's overall performance and efficiency. Without proper cooling, these high-power workhorses risk succumbing to the heat, jeopardizing the entire system's operation. Thus, it is desirable to provide systems and methods to ensure efficient switching transistor cooling in high voltage and high temperature applications. Other desirable features and characteristics of the present disclosure will become apparent from the subsequent detailed description and the appended claims, taken in conjunction with the accompanying drawings and this background discussion.

### BRIEF SUMMARY

Disclosed herein are fluid compression and motor control methods and systems and related electrical systems for provisioning such systems, methods for making and methods for operating such systems, and motor vehicles and other equipment such as aircraft, ships, wind turbines and other electric vehicles equipped with onboard propulsion systems. By way of example, and not limitation, there are presented various embodiments of systems for providing a resilient member to generate a force on a first surface of a switching transistor such that a second surface of the switching transistor pressed against a cooling surface.

### THIS SECTION WILL BE COMPLETED AFTER FINAL CLAIM APPROVAL

### BRIEF DESCRIPTION OF THE DRAWINGS

The present disclosure will hereinafter be described in conjunction with the following drawing figures, wherein like numerals denote like elements, and wherein:

FIG. 1 illustrates an electrically assisted turbocharger for use in an automotive application according to exemplary embodiments of the present disclosure;

FIG. 2 shows an exemplary exploded view of an integrated controller according to exemplary embodiments of the present disclosure;

FIG. 3 illustrates an exemplary cross-sectional view of an integrated controller 300 according to exemplary embodiments of the present disclosure;

FIG. 4 illustrates an exemplary transistor carrier 400 for use in an integrated controller for an EAT according to exemplary embodiments of the present disclosure; and

FIG. 5 illustrates an alternate exemplary transistor carrier 500 for use in an integrated controller for an EAT according to exemplary embodiments of the present disclosure.

### DETAILED DESCRIPTION

The following detailed description is merely exemplary in nature and is not intended to limit the present disclosure or the application and uses of the present disclosure. Furthermore, there is no intention to be bound by any theory presented in the preceding background or the following detailed description.

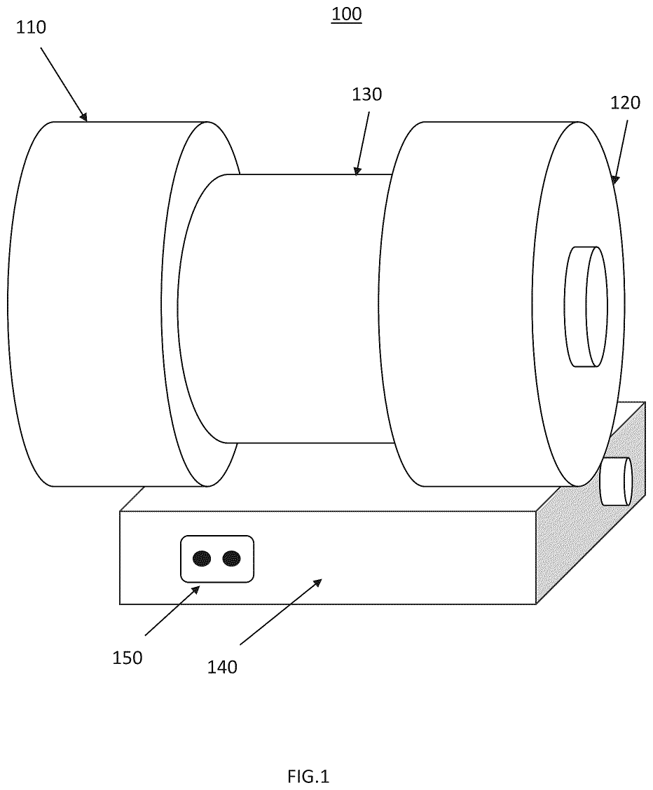

Turning now to FIG. 1, an electrically assisted turbocharger (EAT) 100 for use in an automotive application according to exemplary embodiments of the present disclosure is shown. The exemplary EAT 100 can include a turbocharger having a compressor 120, a turbine 110, an electric motor 130 and an integrated controller 140.

It will be appreciated that the turbocharger 100 could be another turbomachine (e.g., a supercharger, a turbine-less compressor device, etc.) in additional embodiments of the present disclosure. Furthermore, the turbomachine of the present disclosure may be incorporated into a number of systems other than an engine system without departing from the scope of the present disclosure. For example, the turbomachine of the present disclosure may be incorporated within a fuel cell system for compressing air that is fed to a fuel cell stack, or the turbomachine may be incorporated within another system without departing from the scope of the present disclosure.

Generally, the turbocharger 100 may include a stationary portion, including a compressor housing and turbine housing, and a rotating group including a compressor wheel, or impeller, and a turbine connected by a shaft. The rotating group is supported within the stationary portion for rotation about an axis by a bearing system. The bearing system may be of any suitable type, such as a roller-element bearing or an air bearing system. The turbine wheel is located substantially within the turbine housing. The compressor wheel is located substantially within the compressor housing. The shaft extends along the axis of rotation, through the intermediate housing, to connect the turbine wheel to the compressor wheel. Accordingly, the turbine wheel and the compressor wheel may rotate together as a unit about the axis.

In some exemplary embodiments, the turbine 110 is formed by the turbine housing and the turbine wheel configured to circumferentially receive a high-pressure and high-temperature exhaust gas stream from an engine, specifically, from an exhaust manifold of an internal combustion engine. The turbine wheel and, thus, the other components of the rotating group are driven in rotation around the axis by the high-pressure and high-temperature exhaust gas stream 121, which becomes a lower-pressure and lower-temperature exhaust gas stream that is released into a downstream exhaust pipe.

The compressor 120 is formed by the compressor housing and compressor wheel form a compressor stage (i.e., compressor section). In some exemplary embodiments, the compressor 120 can be a centrifugal compressor. The compressor wheel, being driven in rotation by the exhaust-gas driven turbine wheel, is configured to compress received input air (e.g., ambient air, or already-pressurized air from a previous-stage in a multi-stage compressor) into a pressurized airstream that is ejected circumferentially from the compressor housing. The compressor housing may have a shape (e.g., a volute shape or otherwise) configured to direct and pressurize the air blown from the compressor wheel. Due to the compression process, the pressurized air stream is characterized by an increased temperature, over that of the input air.

The exemplary turbocharger 100 further includes an electric motor 130 used to drive, or provide drive assistance, to the rotating group, including the compressor 120, in response to drive currents supplied to the electric motor 130 by the integrated controller 140. In some exemplary embodiments, the electric motor 130 is housed within the turbocharger housing. The shaft may extend through the electric motor 130, and the electric motor 130 may be operably coupled thereto. The electric motor 130 may further be operative as an electric generator. Thus, the e-electric motor 130 may be configured as a motor to convert electrical energy to mechanical (rotational) energy of the shaft for driving the rotating group. Furthermore, the electric motor 130 may be configured as a generator to convert mechanical energy of the shaft to electrical energy that is stored in a battery, etc. As stated, the electric motor 130 may be configured as a combination motor/generator, and the electric motor 130 may be configured to switch functionality between motor and generator modes in some embodiments as well.

Furthermore, the turbocharger 100 can include an integrated controller 140. The integrated controller 140 may generally include a controller housing and a number of internal components (e.g., circuitry, electronic components, cooling components, support structures, etc.) housed within the controller housing. The integrated controller 140 may control various functions. For example, the integrated controller 140 may control the electric motor 130 to thereby control certain parameters (torque, angular speed, START/STOP, acceleration, etc.) of the rotating group. The integrated controller 140 may also be in communication with a battery, an electrical control unit (ECU), or other components of the respective vehicle in some embodiments. More specifically, the integrated controller 140 may receive DC power from a vehicle battery via a DC input 150, and the integrated controller 140 may convert the power to AC power for controlling the electric motor 130. In additional embodiments wherein the electric motor 130 is a combination motor/generator, the integrated controller 140 may operate to switch the electric motor 130 between its motor and generator functionality. Furthermore, the integrated controller 140 may include a number of components that provide robust support and that provide efficient cooling. Thus, the turbocharger 100 may operate at extreme conditions due to elevated temperatures, mechanical loads, electrical loads, etc. Regardless, the integrated controller 140 may be tightly integrated into the turbocharger 100 without compromising performance.

The integrated controller 140 can include a controller housing configured as an outer shell-like member that is hollow and that encapsulates the internal components of the integrated controller 140. Electrical connectors may extend through the housing for electrically connecting the internal components. Furthermore, there may be openings for fluid couplings (e.g., couplings for fluid coolant). Additionally, the controller housing may define part of the exterior of the turbocharger 100. The integrated controller housing can be compactly arranged and integrated with the turbine stage, the compressor stage, and/or other components of the turbocharger 100. Also, internal components of the integrated controller 140 may be in close proximity to the electric motor such that the overall size and profile of the turbocharger 100, including the integrated controller 140, may be very compact. This close proximity can result in various advantages, such as reduced noise for more efficient control of the electric motor, to be closely integrated mechanically to the other components of the turbocharger 100

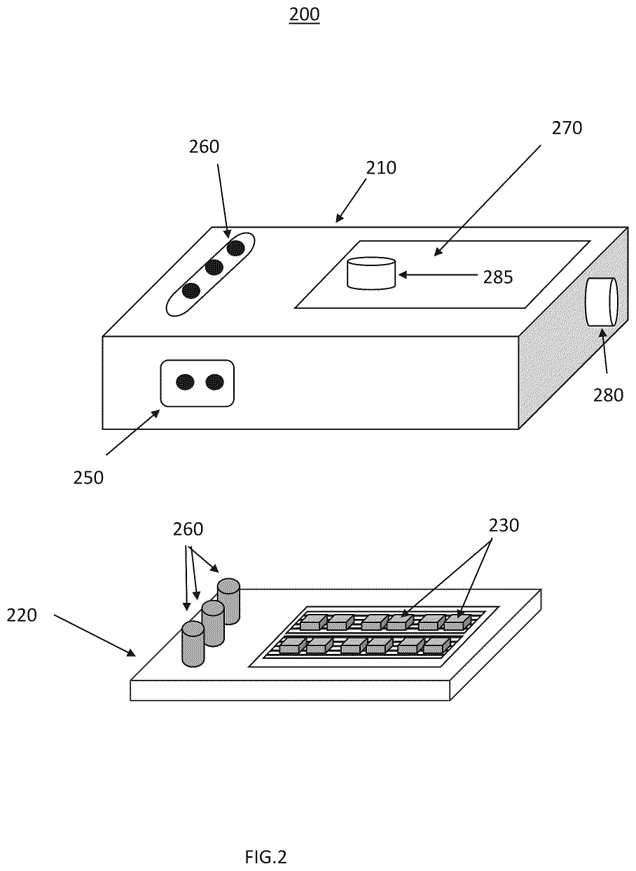

Turning now to FIG. 2, an exemplary exploded view of an integrated controller 200 according to exemplary embodiments of the present disclosure is shown. The exemplary integrated controller 200 includes a controller housing 210 and a transistor carrier 220.

The controller housing 210 is configured to enclose and thermally condition inverter circuitry used to supply AC current to the electric motor as part of the EAT. The controller housing 210 can include a DC interface 250, an AC interface 260, a coolant input 285, a coolant outlet 280, and a coolant pocket 270. During EAT operation, coolant is coupled into the coolant input 285, through the coolant pocket 270 and out of the coolant output 280. When installed into the controller housing 210, the transistor carrier 230 is configured to be affixed within the controller housing 210 such that the switching transistors 230 are thermally coupled to the coolant pocket.

High voltage inverter circuitry requires sufficient clearance distances between high power components, such as AC lead frames and switching transistors 230 to accommodate creepage. In high voltage electronic circuitry, creepage refers to the shortest distance along the surface of an insulating material between two conductors at different potentials. This distance is crucial for preventing unwanted electrical breakdown or arcing, which can damage components and pose safety hazards. Fuel cell compressor inverters for 800V applications are designed with limited space and require that high voltage components are incorporated like AC lead frames & MOSFET switching transistors 230. Sufficient distances must be allowed between these components to prevent unwanted electrical breakdown or arcing between these components which can damage and pose safety hazards

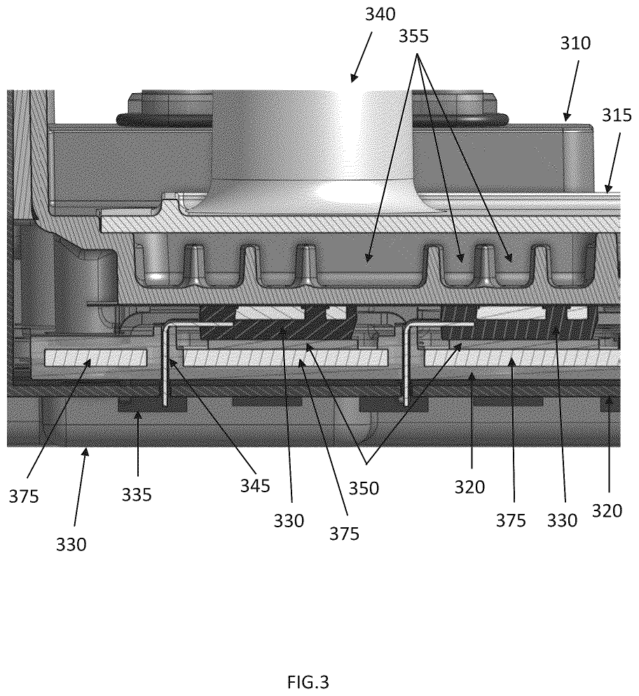

Turning now to FIG. 3, an exemplary cross sectional view of an integrated controller 300 according to exemplary embodiments of the present disclosure is shown. The cross sectional view shows the integrated controller 300 having the transistor carrier 320 installed into the controller housing 310 along with a lower controller housing cover 330. The lower controller housing cover 330 can be configured with thermally and/or electrically conductive gaskets and is configured to be mechanically affixed to the controller housing 310 after installation of the transistor carrier 320 to form a thermal and environmental barrier between the interior of the integrated controller 300 and the outside environment.

The switching transistors 330 are shown integrated into the transistor carrier 320. Each of the switching transistors includes one or more transistor leads 345 for electrically coupling the switching transistor 330 to one or more AC carrier leads on a printed circuit board 320. A printed circuit board 320 is conductively coupled to the switching transistor leads 345 to conduct the AC switching currents to the AC interface 260 of FIG. 2. Nonconductive gaps, such as air gaps, are provided in the lower controller housing cover 330 to prevent shorting of the transistor leads 345 to the lower controller housing cover 330.

The controller housing 310 further includes the coolant pocket 315 including the coolant input 340 and various cooling channels 355 within the coolant pocket 315. Cooling fluid is pumped into the coolant input 340 by an external pump or fluid pressure source and flows through the cooling channels 355 coupling heat from the coolant pocket 315 to the cooling fluid. The heated cooling fluid then flows out of the controller housing 310 via the coolant outlet 280 of FIG. 2.

The transistor carrier 320 is configured with resilient members 350 located between the bodies of the switching transistors 330 and rigid members 375. In some exemplary embodiments, these rigid members 375 can be configured from A285 steel plate and are used to increase the stiffness of the transistor carrier 320 and to prevent deformation of the transistor carrier 320 resulting from the compression of the resilient members 350.

In some exemplary embodiments during inverter operation, the switching transistors 330 are cooled in the controller housing 310 by pressing the upper surface of the switching transistors 330 against a lower surface of the coolant pocket 315 using the resilient pressure of the resilient members 350. In some exemplary embodiments, the resilient member 350 can be a silicon pad or an integrated spring for exerting a force between the rigid members 375 and the bottom surface of the switching transistors 330. The integrated controller 300 is configured such that the resilient member 350 is compressed between the switching transistors 330 and the rigid members 375 such that an optimal resilient member compression is generated to achieve a desired force against the switching transistor 330, such as 80 Newtons. The resulting switching transistor compression further improves noise, vibration and harshness (NVH) performance and improves the clearance and creepage functionalities inside the tight packaging of the integrated controller 300.

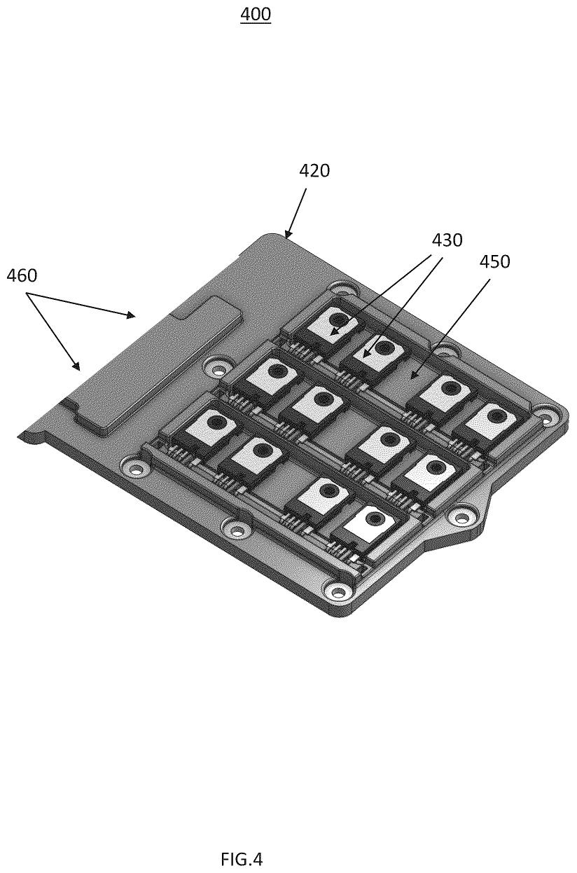

Turning now to FIG. 4, an exemplary transistor carrier 400 for use in an integrated controller for an EAT according to exemplary embodiments of the present disclosure is shown. The exemplary transistor carrier 400 is configured with a plurality of resilient silicon pads 450 for exerting a pressure between a switching transistor bottom surface and a rigid member. The silicon pads 450 are configured to be placed within the transistor carrier 400 before installation of the various switching transistors 430. The switching transistor leads can then be electrically coupled, such as by soldering, to a printed circuit board (not shown) integrated to a bottom surface of the transistor carrier 400. The printed circuit board is further electrically coupled to the AC interface 260 for coupling AC currents to the electric motor of the EAT.

The transistor carrier 400 can be configured such that the top surfaces of the switching transistors 430 project slightly higher from the transistor carrier 400 than the surrounding surfaces. Thus, when the transistor carrier 400 is installed in a controller housing, the top surfaces of the switching transistors 430 are pressed against the lower surface of the coolant pocket with a positive pressure resulting from the compression of the resilient silicon pads 430. This positive pressure assures contact between the coolant pocket and the switching transistors 430, increasing thermal coupling between the coolant pocket and the switching transistors 430 and reducing noise and vibration of the switching transistors 430.

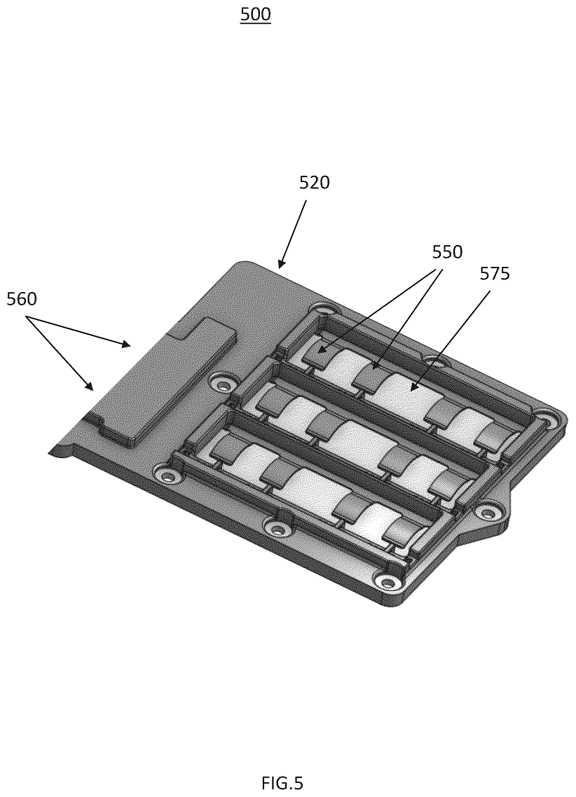

Turning now to FIG. 5, an alternate exemplary transistor carrier 500 for use in an integrated controller for an EAT according to exemplary embodiments of the present disclosure is shown. The exemplary transistor carrier 500 is configured with a plurality of spring fingers 550, such as beryllium copper spring fingers or the like, for exerting a pressure between a switching transistor bottom surface and a rigid member 575. The spring fingers 550 are configured to be placed within the transistor carrier 500 before installation of the various switching transistors 430 of FIG. 4. When the transistor carrier 500 is installed in a controller housing, the top surfaces of the switching transistors 430 of FIG. 4 are pressed against the lower surface of the coolant pocket with a positive pressure resulting from the compression of the spring fingers 550. This positive pressure results in continuous contact between the coolant pocket and the switching transistors 430 of FIG. 4, increasing thermal coupling and reducing noise and vibration of the integrated controller.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the present disclosure in any way. Rather, the foregoing detailed description will provide those skilled in the art with a convenient road map for implementing an exemplary embodiment of the present disclosure. It is understood that various changes may be made in the function and arrangement of elements described in an exemplary embodiment without departing from the scope of the present disclosure as set forth in the appended claims.

What is claimed is:

1. An inverter module comprising:
a rigid frame having an aperture;
a rigid member mechanically affixed to the rigid frame within the aperture;
a transistor positioned within the aperture;
a resilient member arranged within the aperture between a lower surface of the transistor and an upper surface of the rigid member; and
a coolant pocket having a thermally conductive lower surface mechanically affixed to the rigid frame such that the thermally conductive lower surface is in contact with an upper surface of the transistor and wherein the resilient member is compressed between the lower surface of the transistor and the upper surface of the rigid member in response to the coolant pocket being affixed to the rigid frame.

2. The inverter module of claim 1 wherein a compression of the resilient member results in an orthogonal force between the thermally conductive lower surface and the upper surface of the rigid member.

3. The inverter module of claim 1 further including a switching control module for controlling the transistor to generate a three-phase alternating current for coupling to an electric motor.

4. The inverter module of claim 1 further including a printed circuit board electrically coupled to the transistor and affixed to the rigid frame such that the transistor, the rigid member, and the resilient member are positioned between the printed circuit board and the thermally conductive lower surface of the coolant pocket.

5. The inverter module of claim 1 wherein the inverter module is configured to generate a three phase alternating current for driving an electric motor assisted centrifugal compressor.

6. The inverter module of claim 1 wherein the coolant pocket further includes a coolant inlet and a coolant outlet and a plurality of fluid channels for controlling a flow of a coolant such that heat is transferred between the coolant and the thermally conductive lower surface.

7. The inverter module of claim 1 wherein the resilient member is a spring finger.

8. The inverter module of claim 1 wherein the resilient member is a silicon pad.

9. The inverter module of claim 1 wherein the rigid member is a steel plate.

10. A method of arranging an inverter module comprising:
mechanically affixing a rigid member to a rigid frame;
positioning a resilient member on the rigid member within an aperture of the rigid frame;
positioning a transistor on the resilient member such that a lower surface of the transistor is in contact with an upper surface of the resilient member; and
rigidly affixing a coolant pocket having thermally conductive lower surface to the rigid frame such that the thermally conductive lower surface is in contact with an upper surface of the transistor and wherein the resilient member is compressed between the lower surface of the transistor and an upper surface of the rigid member in response to the coolant pocket being affixed to the rigid frame.

11. The method of claim 10 wherein the inverter module includes an outer housing and wherein the coolant pocket forms a portion of the outer housing.

12. The method of claim 10 wherein the resilient member is a thermally conductive spring finger configured to assert a force between the transistor and the rigid member in response to a compression of the thermally conductive spring finger.

13. The method of claim 10 wherein the resilient member is a silicon pad configured to assert a force between the transistor and the rigid member in response to a compression of the silicon pad.

14. The method of claim 10 further including rigidly affixing a printed circuit board to the rigid frame and wherein the transistor is electrically coupled to the printed circuit board through the aperture of the rigid frame though a plurality of leads.

15. The method of claim 10 wherein the rigid member is a steel plate.

16. The method of claim 10 wherein the rigid member is an aluminum plate.

17. The method of claim 10 wherein the coolant pocket encloses a fluid coolant for extracting heat from the thermally conductive lower surface.

18. The method of claim 10 wherein the resilient member is configured to apply a force of 80 newtons between the rigid member and the lower surface of the switching transistor.

19. A inverter module comprising:
a coolant pocket having a coolant input, a coolant outlet and a plurality of coolant channels for controlling a flow of a coolant across an interior side of a thermally conductive wall of the coolant pocket;
a rigid member having an upper side and a lower side;
a resilient member affixed to the upper side of the rigid member;
a transistor having a lower surface in contact with the resilient member and an upper surface in contact with an exterior side of the thermally conductive wall of the coolant pocket;
a plurality of mechanical fasteners for mechanically affixing the rigid member to the coolant pocket such that the resilient member is compressed between the lower surface of the transistor and an upper side of the rigid member in response to the coolant pocket being affixed to the rigid member; and
a printed circuit board rigidly affixed to the second side of the rigid member and electrically coupled to the transistor through an aperture in the rigid member for coupling a direct current and a control signal to the transistor and for receiving a switched current from the transistor.

20. The inverter module of claim 19 wherein the switched current is coupled to an electric motor for driving an impeller in a centrifugal compressor and wherein the inverter module forms a portion of a housing of the centrifugal compressor.
